(19) United States
(12) Patent Application Publication
(10) Pub. No.: US 2026/0319758 A1
(43) Pub. Date: Oct. 15, 2026

(54) INFORMATION PROCESSING DEVICE AND INFORMATION PROCESSING METHOD

(71) Applicant: Renesas Electronics Corporation, Tokyo (JP)

(72) Inventor: Takahiro IKENOBE, Tokyo (JP)

(21) Appl. No.: 19/537,943

(22) Filed: Feb. 12, 2026

Related U.S. Application Data
(60) Provisional application No. 63/757,415, filed on Feb. 12, 2025.

(30) Foreign Application Priority Data
Sep. 18, 2025 (JP) 2025-154963

(51) Int. Cl. G06F 8/30

(52) U.S. Cl. CPC G06F 8/30

(57) ABSTRACT

Provided are an information processing device, an information processing method, and a program that create a DSM contributing to efficient review of RTL code by a designer. An RTL code reading unit reads RTL code. A variable extraction unit extracts variables from the RTL code. A state extraction unit extracts states based on the variables. A data path extraction unit extracts data paths based on the variables. A terminal detection unit detects terminals from the data paths. A graph creation unit creates, based on a relation, graph information in which the states and the terminals of the data paths are connected by edges. A DSM creation unit creates a DSM based on the graph information.

### CROSS-REFERENCE TO RELATED APPLICATIONS

The disclosure of Japanese Patent Application No. 2025-154963 filed on Sep. 18, 2025 including the specification, drawings and abstract is incorporated herein by reference in its entirety.

### BACKGROUND

The present disclosure relates to an information processing device, an information processing method, and a program, and for example, relates to an information processing device, an information processing method, and a program that pertain to design of semiconductor devices.

There are disclosed techniques listed below.

### [Patent Document 1] Japanese Unexamined Patent Application Publication No. 2024-22527

When a logic circuit that performs a predetermined operation is designed, a technique of describing the operation of the logic circuit in a hardware description language, such as a register transfer level (RTL), has been widely used, for example. The design of the logic circuit using the RTL is described in, for example, Patent Document 1.

### SUMMARY

A designer of the logic circuit is required to review whether a specification and design information are accurately reflected in the RTL code that is described according to the specification and the design. However, register variables and wire variables in the RTL code are generally large in number, so that it is not possible to review, accurately and within the scope of realistic effort, whether the specification and the design information are reflected in these variables.

For example, the designer can use a technique, such as a design structure matrix (DSM), to grasp the structure of the RTL code. However, if the DSM is created for all the register variables and the wire variables, the number of cells in the DSM increases. Thus, only using the DSM alone cannot achieve reduction of the effort for the designer to review the RTL code or a guarantee of accuracy.

Other problems and novel features will become apparent from the description of the present specification and the accompanying drawings.

According to an embodiment, an information processing device includes an RTL code reading unit that reads RTL code, a variable extraction unit that extracts variables from the read RTL code, a state extraction unit that extracts states based on the extracted variables, a data path extraction unit that extracts data paths based on the extracted variables, a terminal detection unit that detects, from the extracted data paths, terminals of the data paths, a graph creation unit that creates, based on a relation, graph information in which the extracted states and the detected terminals of the data paths are connected by edges, and a design structure matrix (DSM) creation unit that creates a DSM based on the graph information.

According to an embodiment, an information processing method includes reading RTL code, extracting variables from the read RTL code, extracting states based on the extracted variables, extracting data paths based on the extracted variables, detecting, from the extracted data paths, terminals of the data paths, creating, based on a relation, graph information in which the extracted states and the detected terminals of the data paths are connected by edges, and creating a design structure matrix (DSM) based on the graph information.

According to an embodiment, a program causes a computer to execute processing of reading RTL code, processing of extracting variables from the read RTL code, processing of extracting states based on the extracted variables, processing of extracting data paths based on the extracted variables, processing of detecting, from the extracted data paths, terminals of the data paths, processing of creating, based on a relation, graph information in which the extracted states and the detected terminals of the data paths are connected by edges, and processing of creating a design structure matrix (DSM) based on the graph information.

According to the embodiments, the information processing device, the information processing method, and the program that create the DSM contributing to efficient review of the RTL code by a designer can be provided.

### BRIEF DESCRIPTION OF THE DRAWINGS

FIG. 1 is a diagram illustrating procedures of general digital circuit design using RTL code.

FIG. 2 is a block diagram schematically illustrating a configuration of an information processing device according to a first embodiment.

FIG. 3 is a flowchart illustrating an operation of the information processing device according to the first embodiment.

FIG. 4 is a diagram illustrating an example of RTL code.

FIG. 5 is a diagram illustrating the example of the RTL code.

FIG. 6 is a diagram illustrating an example of a terminal of data paths.

FIG. 7 is a diagram illustrating an example of a graph created by a graph creation unit.

FIG. 8 is a diagram illustrating an example of a DSM created by the information processing device according to the first embodiment.

FIG. 9 is a diagram illustrating an example of a DSM created from RTL code by a general technique.

FIG. 10 is a flowchart illustrating an operation of an information processing device according to a second embodiment.

FIG. 11 is a diagram illustrating an example in which states in the RTL code illustrated in FIGS. 4 and 5 are numbered.

FIG. 12 is a diagram illustrating a difference in the DSM before and after ordering.

FIG. 13 is a flowchart illustrating an operation of an information processing device according to a third embodiment;

FIG. 14 is a diagram illustrating an example of a DSM displaying a clustering result.

FIG. 15 is a diagram illustrating a configuration example of a computer for achieving the information processing device.

### DETAILED DESCRIPTION

Hereunder, embodiments of the present invention will be described with reference to the drawings. In the drawings, the same elements are denoted by the same reference signs, and redundant description will be omitted as necessary.

As a premise for understanding the configuration and operation of an information processing device according to the following embodiments, procedures of general digital circuit design using register transfer level (RTL) code and problems thereof will be described.

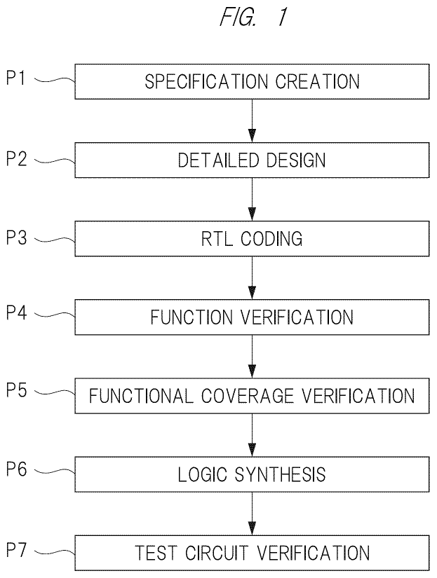

FIG. 1 is a diagram illustrating the procedures of the general digital circuit design using the RTL code. In specification creation P1, first, a configuration and a function of a circuit to be designed are defined by a document and a drawing. In the specification creation P1, for example, a function description, a register description, a flowchart, and the like are created.

In detailed design P2, more detailed design information is created based on the information created in the specification creation P1. In the detailed design P2, for example, a state transition diagram (also referred to as a finite state machine (FSM) diagram), a data processing flow, a timing chart, and the like are created.

In RTL coding P3, a designer creates RTL code based on the design information created in the detailed design P2.

In function verification P4, the designer verifies whether the RTL code runs as specified by the specification information, through simulation or the like.

In functional coverage verification P5, to prevent omission of the verification through simulation, the designer verifies, using, for example, various tools, whether a specific condition or operation normally functions.

In logic synthesis P6, the designer converts the RTL code subsequent to the above-described verification into a gate-level netlist using, for example, various tools. At this time, the designer may verify whether the logic synthesis result matches the RTL code.

In test circuit verification P7, the designer fabricates a real device based on the logic synthesis result. Then, operation verification and timing analysis are performed on the fabricated real device to verify whether the design information is reflected in the real device.

The designer designs and verifies digital circuits through the above-described procedures, but there are problems in the detailed design P2 and the RTL coding P3. In the detailed design P2, the designer confirms whether the specification information created in the specification creation P1 is accurately reflected in the design information created in the detailed design P2. However, in the FSM diagram, for example, there is a case where descriptions of operations are scattered without converging to one location due to branching of a state, additional design, or the like. Although a timing signal for starting processing is designated by the timing chart, it is generally difficult to grasp relations with states in the FSM diagram. Hence, there is a risk that the designer may overlook an operation that is not consistent, in the design information created in the detailed design P2, with the specification information created in the specification creation P1.

Further, in the RTL coding P3, there is necessity for the designer to review whether transition order and transition timings of the states designated in the FSM diagram are accurately reflected in the RTL code. The designer is also required to review whether element parts are appropriately used in the RTL code, such as whether an appropriate register is allocated to a predetermined operation. However, since the data processing is individually described in the RTL code, it is difficult for the designer to grasp the flow of the processing. It is also difficult for the designer to grasp which process described in the RTL code operates according to input.

In the following embodiments, therefore, an information processing device will be described that generates, from the RTL code, a design structure matrix (DSM) capable of alleviating a burden required of the designer for the review of the RTL code.

### First Embodiment

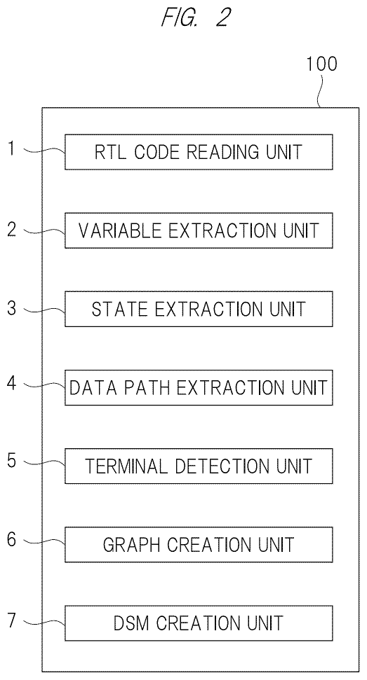

An information processing device according to a first embodiment is enabled to generate a DSM from RTL code. FIG. 2 is a block diagram schematically illustrating a configuration of the information processing device according to the first embodiment. An information processing device 100 includes an RTL code reading unit 1, a variable extraction unit 2, a state extraction unit 3, a data path extraction unit 4, a terminal detection unit 5, a graph creation unit 6, and a DSM creation unit 7.

The RTL code reading unit 1 reads RTL code. The variable extraction unit 2 extracts register variables and wire variables from the RTL code. The state extraction unit 3 extracts states from the RTL code. The data path extraction unit 4 extracts data paths from the RTL code. The terminal detection unit 5 detects terminals of the extracted data paths. The graph creation unit 6 creates graph information from the extracted states and the detected terminals of the data paths. The DSM creation unit 7 creates a DSM based on the graph information.

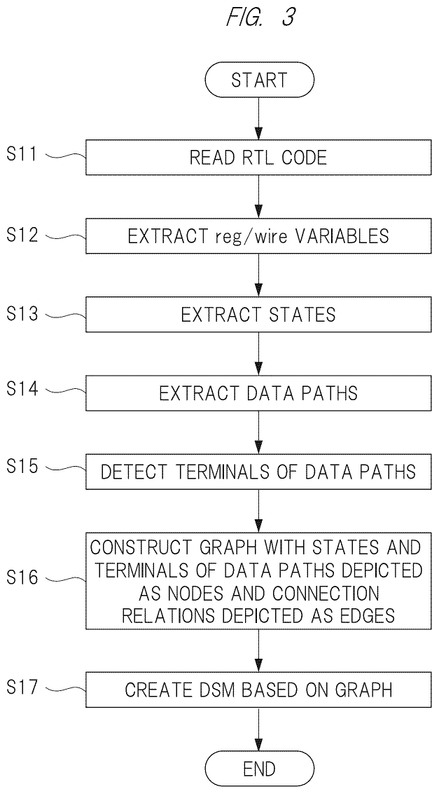

Hereunder, procedures of DSM creation processing in the information processing device 100 will be described. FIG. 3 is a flowchart illustrating an operation of the information processing device according to the first embodiment.

### Step S11

The RTL code reading unit 1 reads RTL code. The RTL code reading unit 1 outputs the read RTL code to the variable extraction unit 2.

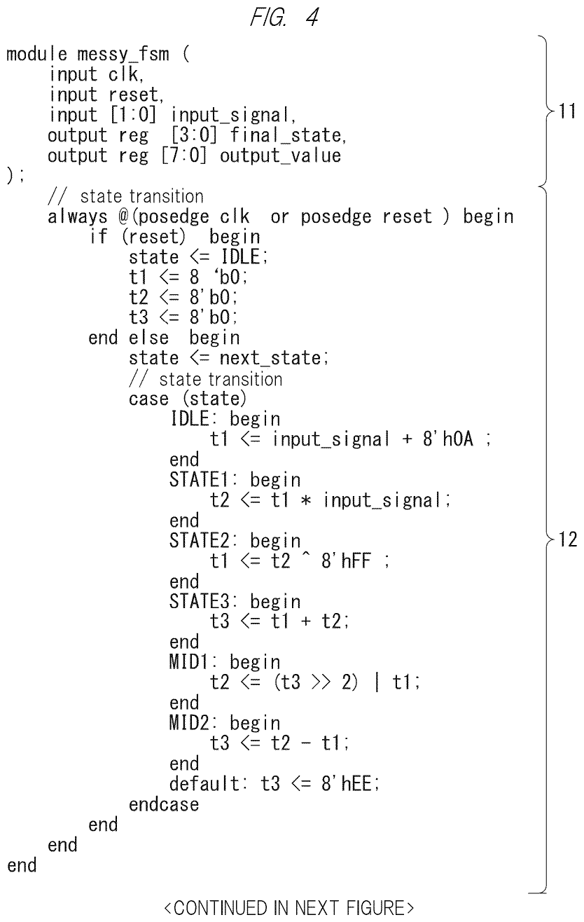

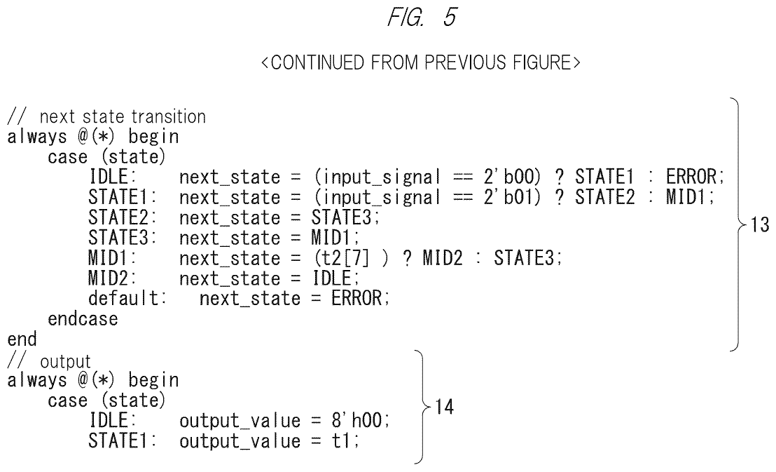

FIGS. 4 and 5 are diagrams illustrating an example of the RTL code. A portion indicated by reference sign 11 in FIG. 4 is a portion in which a module declaration and port definitions are described. Here, clk, reset, and input_signal are defined as input values. In addition, final_state and output_value are defined as register type values. A portion indicated by reference sign 12 in FIG. 4 is a portion in which definitions of states are described. In this example, six states: IDLE, STATE1 to STATE3, MID1, and MID2, are defined. Then, processing to be executed in each state is defined. A portion indicated by reference sign 13 in FIG. 5 is a portion in which transitions of the states are described. Here, states the current states transition to next are defined. A portion indicated by reference sign 14 in FIG. 5 is a portion in which definitions of data output are described. Here, values to be output as output values: output_value, are defined according to conditions.

### Step S12

The variable extraction unit 2 extracts register variables and wire variables from the RTL code.

### Step S13

The state extraction unit 3 extracts states (STATE) from the extracted register variables and wire variables. The state mentioned here is not a state, in a narrow sense, indicating an operation mode or an operation phase of a device or the like in a state transition diagram, for example. Hereunder, the state means all values held in flip-flops, such as an operation mode of a device, a counter value, a timer value, a flag, and a parameter.

In the RTL code of FIGS. 4 and 5, the state extraction unit 3 can extract states by extracting positions where non-blocking assignment is performed. In the example of FIGS. 4 and 5, the state extraction unit 3 extracts, as the states, IDLE, STATE1 to STATE3, MID1, MID2, and ERROR that indicate operation states, from the description of the RTL code. In addition, the state extraction unit 3 extracts, as the states, the input value: input_signal, the output value: output_value, and the parameters: final_state and t1 to t3, from the description of the RTL code.

### Step S14

The data path extraction unit 4 extracts data paths from the RTL code. The data path is a data processing flow without feedback, the flow being represented by a register and a combinational circuit. In the RTL code of FIGS. 4 and 5, the data path extraction unit 4 extracts, as the data paths, the input value: input_data, a flow of processing related to parameters to be calculated: t1 to t3, and the generation of the output value: output_value.

### Step S15

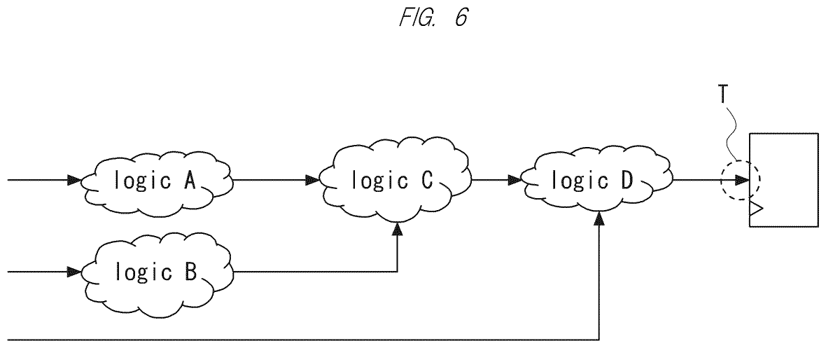

The terminal detection unit 5 detects terminals of the data paths extracted by the data path extraction unit 4. The terminal mentioned here refers to an output terminal from a combinational circuit to a flip-flop in a data path without feedback. FIG. 6 is a diagram illustrating an example of a terminal of data paths. In FIG. 6, data calculated by four combinational circuits: logic A to logic D, is output to a flip-flop. In this case, the terminal detection unit 5 detects, as a terminal T, a path for outputting data from the last logic D to the flip-flop. This enables intermediate calculation results up to the terminal to be excluded. As a result, it is possible to effectively minimize the number of data paths listed as items (described later) of a DSM.

### Step S16

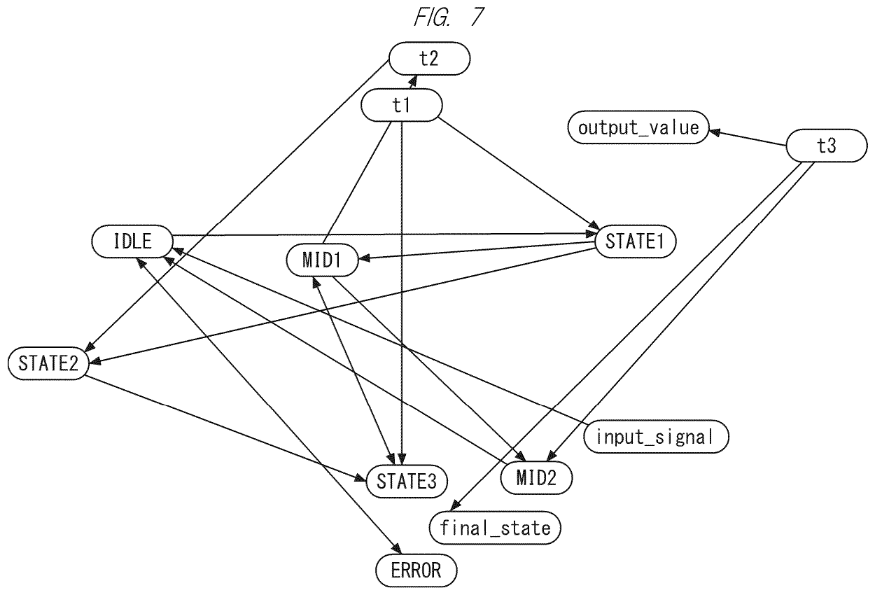

The graph creation unit 6 generates edges connecting between the extracted states and the detected terminals of the data paths, from relations between the states and the terminals of the data paths. Then, the extracted states and the detected terminals of the data paths are determined as nodes, and graph information in which the nodes are connected by the generated edges is generated. FIG. 7 is a diagram illustrating an example of a graph created by the graph creation unit. As illustrated in FIG. 7, the graph information in which the states and the data path terminals are connected by the edges is created.

### Step S17

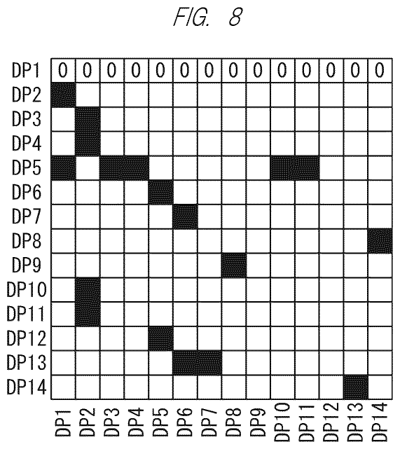

The DSM creation unit 7 creates a DSM based on the graph information created by the graph creation unit 6. FIG. 8 is a diagram illustrating an example of a DSM created by the information processing device according to the first embodiment. FIG. 8 is an example of a DSM created for exemplary data paths DP1 to DP14. As described above, according to the information processing device 100, it is possible to narrow down the items to the states or the terminals of the data paths and create the DMS in which the number of cells is minimized.

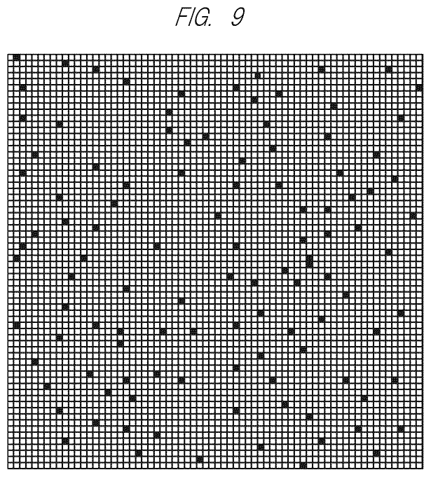

Next, advantages of the DSM created by the information processing device 100 will be described. First, as a premise for understanding the advantages of the DSM, a case where the DSM is created from the RTL code by a general technique will be discussed. FIG. 9 is a diagram illustrating an example of a DSM created from RTL code by a general technique. For simplification of the figure, the items of the DSM are omitted in FIG. 9. The general technique mentioned here corresponds to a case where steps S13 to S15 in FIG. 3 are skipped to create a DSM. The RTL code contains various types of components, such as wiring, registers, arithmetic processing, and conditional branching. Even in relatively simple RTL code, the number of components is as many as several tens to several hundreds. Hence, the numbers of register variables and wire variables extracted from the RTL code become enormous. This increases the numbers of rows and columns in the DSM, and the DSM consequently contains an extremely large number of cells. When such a large-scale and complex DSM is used, the designer is unable to perform efficient and accurate design review.

By contrast, with the information processing device according to the present embodiment, the information extracted from the RTL code is narrowed down to the states and the terminals of the data paths associated with the states. This enables the numbers of rows and columns in the DSM to be reduced and the number of cells to be minimized to the extent that the designer can analyze the structure. As a result, the designer is able to perform efficient and accurate design review using the DSM created by the information processing device 100.

### Second Embodiment

The information processing device 100 according to the first embodiment creates the DSM based on the declaration order of the variables in the RTL code. In the RTL code, on the other hand, the register variables and the wire variables are declared independently of the processing flow in some cases. Hence, when a DSM in which items are laid out in declaration order in the RTL code is created, the designer may not be able to review the flow of processing based on the DSM.

By contrast, with an information processing device according to a second embodiment, DSM creation processing by a DSM creation unit 7 is changed to perform ordering for adjusting an arrangement of rows and columns of a DSM so as to facilitate the designer's grasp of the flow of the processing defined by the RTL code.

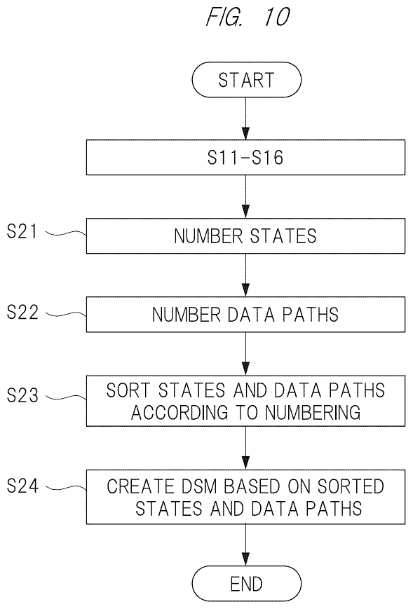

FIG. 10 is a flowchart illustrating an operation of the information processing device according to the second embodiment. In FIG. 10, step S17 in FIG. 3 is replaced with steps S21 to S24 of creating an ordered DSM. Since steps S11 to S16 are similar, redundant description is omitted.

### Step S21

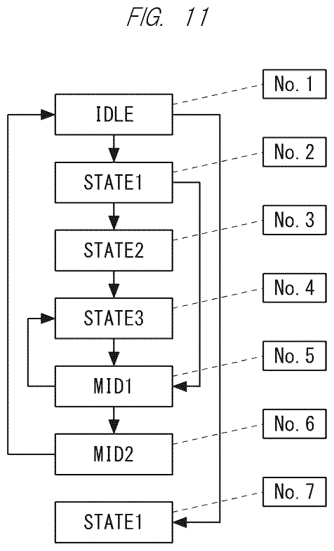

The DSM creation unit 7 analyzes transition order of the extracted states from dependency relations of the states. Then, the DSM creation unit 7 numbers the states according to the transition order. FIG. 11 is a diagram illustrating an example in which the states in the RTL code illustrated in FIGS. 4 and 5 are numbered. As described above, the DSM creation unit 7 numbers the states according to the flow of the states.

### Step S22

The DSM creation unit 7 analyzes processing order from dependency relations of the extracted data paths. Then, the DSM creation unit 7 numbers the data paths according to the processing order. The method of the numbering is similar to the case for the states.

### Step S23

The DSM creation unit 7 sorts the states based on their numbering result. The DSM creation unit 7 sorts the data paths based on their numbering result.

### Step S24

The DSM creation unit 7 sets the sorted states and data paths to rows and columns to create a DSM.

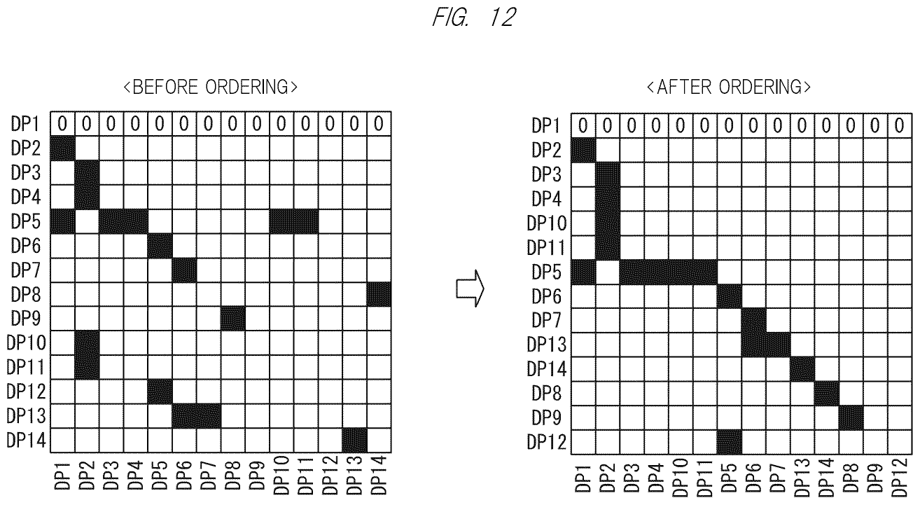

FIG. 12 is a diagram illustrating a difference in the DSM before and after the ordering. As illustrated in FIG. 12, items of the DSM are ordered by an information processing device 200 to enable connected colored cells to be laid out and arranged from an upper left to a lower right of the DSM according to the order of the processing. This enables the designer to grasp the flow of the processing to perform review with further reduced omissions.

### Third Embodiment

In the DSM, when the scale of the RTL code to be analyzed increases, the number of cells increases in proportion to the square of the number of items. Hence, when the number of items increases, there is a high possibility that the designer is unable to check each item without omission.

By contrast, with an information processing device according to a third embodiment, DSM creation processing by a DSM creation unit 7 is changed to create a DSM in which cells to be checked by a designer are narrowed down.

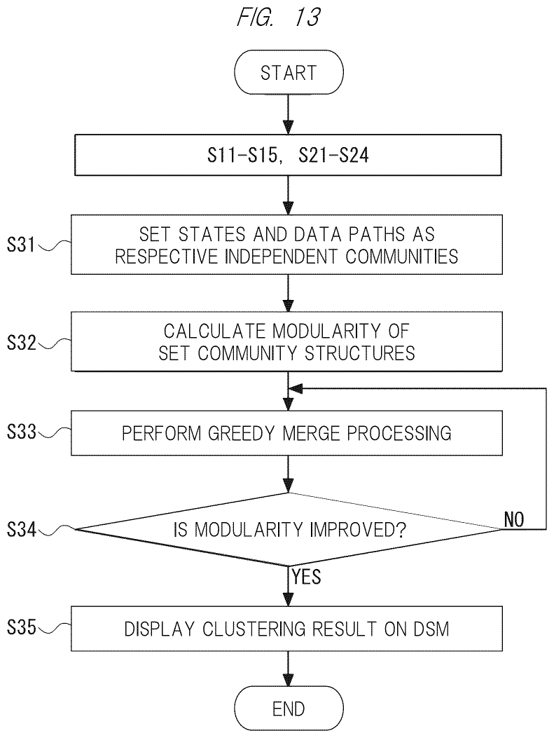

FIG. 13 is a flowchart illustrating an operation of the information processing device according to the third embodiment. In FIG. 13, steps S31 to S35 are added after step S24 in FIG. 10. The DSM creation unit 7 clusters the DSM items, i.e., the nodes, that are subjected to the ordering, using modularity through steps S31 to S34. Since steps S11 to S16 and S21 to S24 are similar, redundant description is omitted.

### Step S31

The DSM creation unit 7 initializes the states and the data paths as respective independent communities.

### Step S32

The DSM creation unit 7 calculates modularity of current community structures.

### Step S33

The DSM creation unit 7 performs greedy merge of the nodes based on the modularity. For example, the DSM creation unit 7 selectively merges community pairs. Next, the DSM creation unit 7 calculates modularity of structures that are subjected to the community merge. Then, the DSM creation unit 7 selects communities with improved modularity based on the calculation result.

### Step S34

The DSM creation unit 7 determines whether the modularity of the structures containing the communities that are subjected to the merge is improved as compared with the modularity of the structures containing the communities that are not subjected to the merge. When the modularity is not improved, the DSM creation unit 7 returns the processing to step S33.

### Step S35

When the modularity is improved, the DSM creation unit 7 displays the clustering result on the DSM.

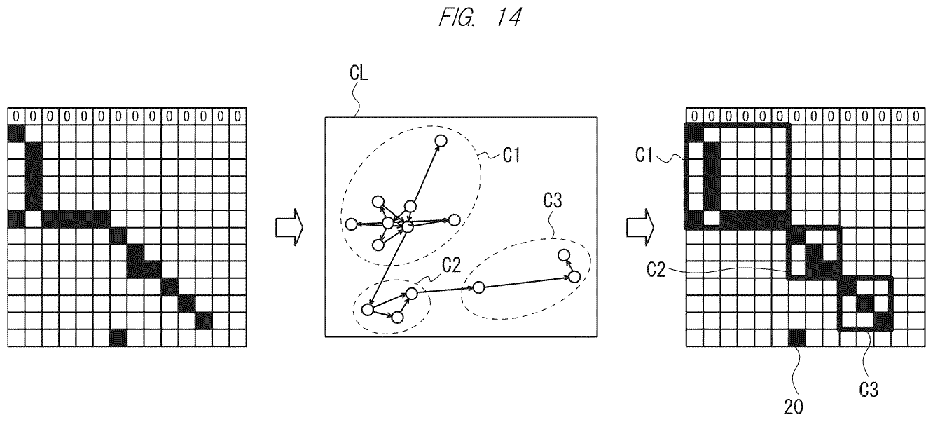

FIG. 14 is a diagram illustrating an example of the DSM displaying the clustering result. For simplification of the figure, the items of the DSM are omitted in FIG. 14. FIG. 14 illustrates a case where the DSM items subjected to the ordering illustrated in FIG. 12 are clustered (reference sign: CL) into communities C1 to C3. Then, the clustering result is displayed separately for each community by a bold frame in the DSM subjected to the ordering. This makes it possible to effectively minimize the number of cells to be reviewed, by focusing on the cells in each group, if the scale of the DSM is large. When there is a cell outside the communities as in a cell 20 in FIG. 14, the designer can easily grasp that the operation of the cell is unique.

Note that the above-described clustering method is merely an example. As long as the DSM items can be suitably clustered, other various clustering techniques may be used.

### Other Embodiments

While the present disclosure is described with reference to the embodiments, the present disclosure is not limited to the above-described embodiments. Various alterations understandable by those skilled in the art can be made, within the scope of the present disclosure, to the configuration and details of the present disclosure. Each embodiment may be appropriately combined with another embodiment.

In the above-described embodiments, the information processing device according to the present disclosure is mainly described as a hardware configuration; however, the present disclosure is not limited thereto. It is also possible to achieve the information processing device according to the present disclosure by causing a computer to execute a computer program to execute certain processing. The processing may be achieved by causing a computer including at least one processor (e.g., a microprocessor, a CPU, a GPU, an MPU, a digital signal processor (DSP)) to execute a program. Specifically, one or a plurality of programs may be created and supplied to a computer, the program(s) including a command group for causing the computer to implement an algorithm related to transmission signal processing or reception signal processing.

The computer program(s) can be stored using a non-transitory computer-readable medium of various types and supplied to the computer. The non-transitory computer-readable medium includes a tangible storage medium of various types. Examples of the non-transitory computer-readable medium include a magnetic recording medium (i.e., a flexible disk, a magnetic tape, or a hard disk drive), a magneto-optical recording medium (e.g., a magneto-optical disk), a CD-read-only memory (ROM), a CD-R, a CD-R/W, and a semiconductor memory (e.g., a mask ROM, a programmable ROM (PROM), an erasable PROM (EPROM), a flash ROM, or a random-access memory (RAM)). In addition, the program(s) may be supplied to the computer by a transitory computer-readable medium of various types. Examples of the transitory computer-readable medium include an electrical signal, an optical signal, and an electromagnetic wave. The transitory computer-readable medium can supply the program(s) to the computer via a wired communication path, such as an electric wire and an optical fiber, or a wireless communication path.

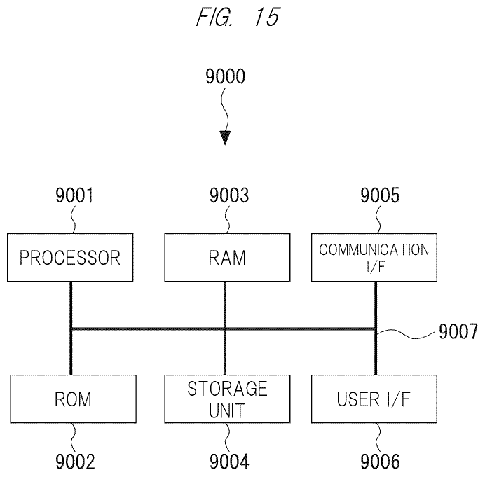

Hereunder, a configuration example of a computer for achieving the information processing device according to the above-described embodiments will be described. FIG. 15 is a diagram illustrating a configuration example of the computer for achieving the information processing device. The information processing device can be achieved by a computer 9000, such as a dedicated computer, a microcomputer, and a personal computer (PC). It is not necessary that the number of computers be physically single, and the number may be plural when distributed processing is executed. As illustrated in FIG. 15, the computer 9000 includes, for example, a processor 9001, a read-only memory (ROM) 9002, a random-access memory (RAM) 9003, a storage unit 9004, a communication interface 9005, and a user interface 9006.

The processor 9001, the ROM 9002, the RAM 9003, the storage unit 9004, the communication interface 9005, and the user interface 9006 are communicably connected to each other via a bus 9007. While the description of OS software for operating the computer and the like is omitted, the OS software and the like are appropriately introduced to the computer 9000.

The ROM 9002 is, for example, a nonvolatile semiconductor storage. The ROM 9002 stores information, such as various programs used in the computer 9000.

The storage unit 9004 is, for example, a storage of various types, such as a hard disk and a solid-state disk. The storage unit 9004 is not limited to the storage mounted on the computer 9000, and may be a storage outside the computer 9000. The storage outside the computer 9000 may be a cloud storage connected to the computer 9000 via communication means of various types, such as a network. The storage unit 9004 stores information, such as various programs and data used in the computer 9000.

The RAM 9003 is a volatile semiconductor storage or the like. Information of programs and data used by the processor 9001 is loaded into the RAM 9003 from one or both of the ROM 9002 and the storage unit 9004 as appropriate.

The processor 9001 may be configured with, for example, a central processing unit (CPU) or the like. The processor 9001 may be provided with not only a CPU but also a graphics processing unit (GPU). The GPU is suitable for an application in which routine processing is performed in parallel, and for example, by applying the GPU to processing in a neural network or the like, processing speed can be accelerated as compared with the CPU. The processor 9001 appropriately executes various processing based on the various programs stored in the ROM 9002 or the various programs and data stored in the RAM 9003. The processor 9001 may appropriately store data generated by the processing, in the RAM 9003 or the storage unit 9004.

The communication interface 9005 is an interface that connects the computer 9000 and a communication network, such as the Internet and an intranet, via wired communication means or wireless communication means of various types. This enables the computer 9000 to communicate with another device, system, sensor, and the like that are connected to the communication network.

The user interface 9006 includes, for example, a voice output unit that performs output by voice, and a display unit that provides information in such a way that the user can recognize the information with a display display or the like. The user interface 9006 includes an input unit, such as a keyboard, a mouse, and a touch panel, that allows information to be input to the computer 9000 through user's operation. The user interface 9006 may include equipment, such as a sensor, that allows information useful for the user to be acquired.

The computer 9000 is described as one device herein; however, this is merely an example. The computer 9000 may be configured with a plurality of physically separated devices. One or some of the plurality of devices may be a portable device(s), and another one or the other ones may be a stationary device(s).

The overcurrent detection threshold value, and the threshold value and the slew rate that are used for switching the slew rate of the output transistor, which are described in the above-described embodiments, may be stored in the ROM 9002, the RAM 9003, or the like of the computer 9000 that functions as the control circuit. The processor may then appropriately read the threshold values and the slew rate from the ROM 9002, the RAM 9003, or the like, and set the read values to the overcurrent detection circuit and the drive circuit. In addition, the overcurrent detection threshold value, and the threshold value and the slew rate that are used for switching the slew rate of the output transistor may be input and output via the communication interface 9005, such as a serial peripheral interface (SPI), or the user interface 9006.

Each drawing is merely an example for describing one or more embodiments. Each drawing is not associated with only one particular embodiment, and may be associated with one or more other embodiments. As those skilled in the art understand, various features or steps described with reference to any one of the drawings may be combined with a feature(s) or a step(s) illustrated in one or more other drawings, for example, in order to devise an embodiment that is not explicitly depicted or described. All of the features or steps illustrated in any one of the drawings for describing the exemplary embodiments are not necessarily indispensable, and some features or steps may be omitted. The order of the steps described in any drawing may be changed as appropriate.

What is claimed is:

1. An information processing device comprising:
an RTL code reading unit that reads RTL code;
a variable extraction unit that extracts variables from the read RTL code;
a state extraction unit that extracts states based on the extracted variables;
a data path extraction unit that extracts data paths based on the extracted variables;
a terminal detection unit that detects, from the extracted data paths, terminals of the data paths;
a graph creation unit that creates, based on a relation, graph information in which the extracted states and the detected terminals of the data paths are connected by edges; and
a design structure matrix (DSM) creation unit that creates a DSM based on the graph information.

2. The information processing device according to claim 1,
wherein the variable extraction unit extracts a register variable and a wire variable from the RTL code.

3. The information processing device according to claim 1,
wherein the DSM creation unit
numbers the extracted states based on transition order,
numbers the detected terminals of the data paths based on processing order, and
sorts, based on numbering results, items in a DSM to be created.

4. The information processing device according to claim 3,
wherein the DSM creation unit
clusters the sorted items based on the numbering results, and
displays, on the DSM, communities in which the items are classified by the clustering.

5. The information processing device according to claim 4,
wherein the DSM creation unit clusters the items that are sorted based on the numbering results, by performing greedy merge of communities based on modularity.

6. An information processing method comprising:
reading RTL code;
extracting variables from the read RTL code;
extracting states based on the extracted variables;
extracting data paths based on the extracted variables;
detecting, from the extracted data paths, terminals of the data paths;
creating, based on a relation, graph information in which the extracted states and the detected terminals of the data paths are connected by edges; and
creating a design structure matrix (DSM) based on the graph information.

7. A computer readable storage medium causing a computer to execute:
processing of reading RTL code;
processing of extracting variables from the read RTL code;
processing of extracting states based on the extracted variables;
processing of extracting data paths based on the extracted variables;
processing of detecting, from the extracted data paths, terminals of the data paths;
processing of creating, based on a relation, graph information in which the extracted states and the detected terminals of the data paths are connected by edges; and
processing of creating a design structure matrix (DSM) based on the graph information.
